(19) United States
(12) Patent Application Publication
(10) Pub. No.: US 2009/0026447 A1
(43) Pub. Date: Jan. 29, 2009

(54) Light emitting device

(75) Inventors: Masato ITO, Mobara (JP); Hiroshi Oooka, Mobara (JP); Hirotsugu Sakamoto, Chiba (JP)

Correspondence Address: Stanley P. Fisher;Reed Smith LLP, Suite 1400, 3110 Fairview Park Drive, Falls Church, VA, 22042-4503, US

(73) Assignee: Hitachi Displays, Ltd.

(21) Appl. No.: 12/219,363

(22) Filed: Jul. 21, 2008

(30) Foreign Application Priority Data
Jul. 25, 2007 (JP) 2007-193858

(51) Int. Cl. H01L 35/24

(52) U.S. Cl. 257/40; 257/E51.018

(57) ABSTRACT

An organic EL display device having a long lifetime is provided. The light emitting device includes at least one organic compound layer between a pair of electrodes, and the content of an impurity generated from an organic compound in the at least one organic compound layer is 10 ng/cm² or less in terms of hexadecane or the number of impurities generated from the organic compound is 10 or less.

### CLAIM OF PRIORITY

The present invention claims priority from Japanese application serial No. 2007-193858, filed on Jul. 25, 2007, the content of which is hereby incorporated by reference into this application.

### BACKGROUND OF THE INVENTION

1. Field of the Invention

The present invention relates to a light emitting device including an organic compound layer between a pair of electrodes.

2. Description of the Related Art

In general, a low-molecular organic electroluminescent device (OLED) is formed by forming a multi-layer thin film organic layer between an anode and a cathode. This organic layer is made of a high-purity material, and when an impurity exists in the thin film, the characteristics and the lifetime of the OLED device are much influenced. Specifically, the impurity becomes a trap site for holes or electrons, and hinders current flow. Thus, in order to cause the OLED to emit light, it becomes necessary to increase a voltage. When the voltage is increased, the lifetime of the light emitting device becomes short. It is known that a material is decomposed during evaporation and this impurity is generated. The generated impurity accelerates the decomposition of an organic compound constituting the main component, and causes an abrupt reduction in luminance.

An attempt is made to regulate a relation between an impurity and the lifetime of a light emitting device. Patent document 1 discloses that an impurity included in the composite stage of NPD influences the reliability. Patent documents 2 and 3 disclose that when an impurity is included in an organic compound layer, the reliability is influenced. It is regulated that the impurity amount is 1.0% or less.

Patent document 1: JP-A-2002-235077 (US2002/0146590A1)

Patent document 2: JP-A-2002-373785

Patent document 3: JP-A-2003-68467

However, there is also such an impurity that even if the impurity concentration at the time of refining is high, the reliability is not influenced. Besides, when impurities generated at the time of film growth of an organic compound layer are not considered at all, even if the impurity amount at the time of refining is decreased, the lifetime is not necessarily increased. Besides, among impurities, there is an impurity which does not influence the reliability, and even if this impurity of 1.0% or more is included, there is no problem. That is, in the related art, it is not sufficiently studied that to what degree impurities have to be decreased.

### SUMMARY OF THE INVENTION

As a new approach, the present inventors contrived to realize a light emitting device having a long lifetime by controlling production conditions of the number of impurities and the weight per area. Specifically, a light emitting device includes at least one organic compound layer between a pair of electrodes, and the content of an impurity generated from an organic compound in the at least one organic compound layer is 10 ng/cm² or less in terms of hexadecane. Besides, from another viewpoint, a light emitting device includes at least one organic compound layer between a pair of electrodes, and the number of impurities generated from an organic compound in the at least one organic compound layer is 10 or less.

According to the invention, the lifetime of a display device can be increased.

### BRIEF DESCRIPTION OF THE DRAWINGS

FIG. 1 is a schematic sectional view for explaining a structure of an organic EL device.

FIG. 2 is a view for explaining the presence or absence of immediately preceding chamber cleaning, ozone cleaning (presence or absence, the number of times), the number of times of immediately preceding trial manufacture in examples 1 to 4 and comparative examples 1 and 2.

FIG. 3 is an explanatory view of fabrication conditions of light emitting devices corresponding to the examples and the comparative examples of FIG. 2.

FIG. 4 is a view showing a relation between impurity amount and half luminance lifetime.

FIG. 5 is a view showing a relation between purity and half luminance lifetime.

FIG. 6 is a view for explaining the presence or absence of immediately preceding chamber cleaning, ozone cleaning (presence or absence, the number of times), the number of times of immediately preceding trial manufacture in examples 5 to 8 and comparative examples 3 and 4.

FIG. 7 is an explanatory view of analysis results and half luminance lifetime (hr).

FIG. 8 is a view for explaining a relation between the impurity amount of the whole organic layer and the half luminance lifetime.

FIG. 9 is a view for explaining a relation between the number of impurities and the half luminance lifetime.

FIG. 10 is a view for explaining the presence or absence of immediately preceding chamber cleaning, ozone cleaning (presence or absence, the number of times), the number of times of immediately preceding trial manufacture in examples 9 to 12 and comparative examples 5 and 6.

FIG. 11 is an explanatory view of analysis results and half luminance lifetime (hr).

FIG. 12 is a view for explaining a relation between impurity amount and half luminance lifetime.

### DESCRIPTION OF THE PREFERRED EMBODIMENTS

Hereinafter, examples will be described.

### EXAMPLE 1

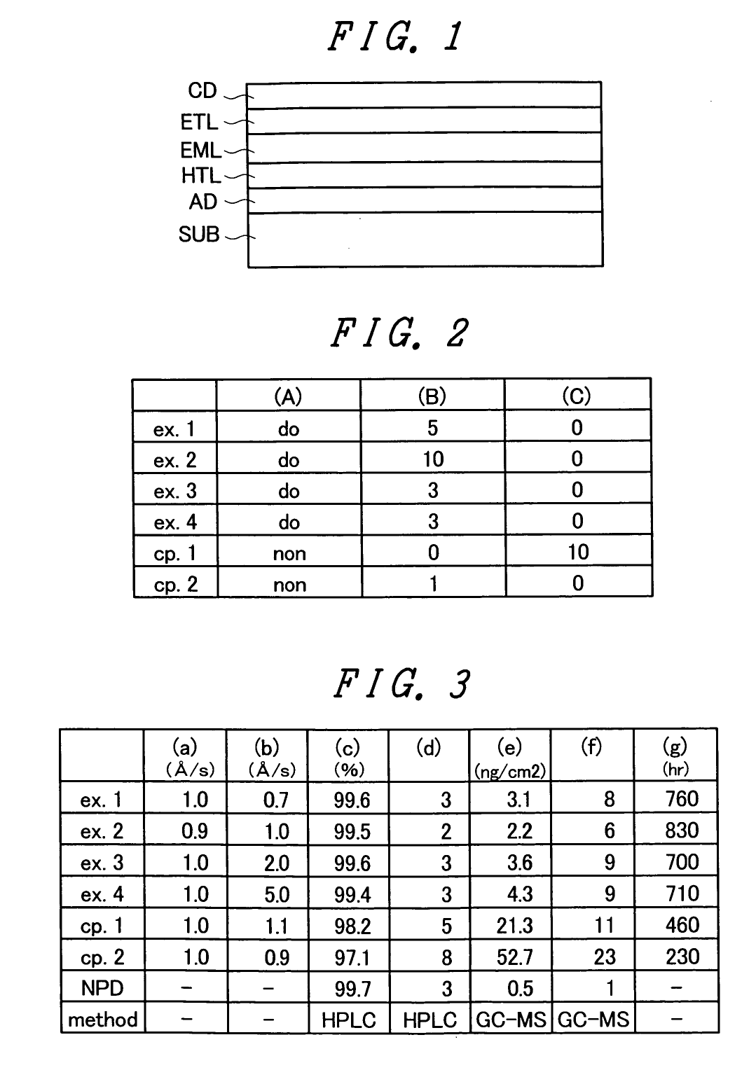

FIG. 1 is a schematic sectional view for explaining a structure of an organic EL device. The organic EL device has a structure including a substrate SUB, an anode AD disposed on the substrate SUB, a hole transport layer HTL disposed on the anode AD, a light emitting layer EML disposed on the hole transport layer HTL, an electron transport layer ETL disposed on the light emitting layer, and a cathode CD disposed on the electron transport layer ETL.

Next, a process of producing the organic EL device having the structure shown in FIG. 1 will be described. First, a glass substrate SUB is prepared, an ITO film (thickness of 80 nm) is grown by sputtering, and is crystallized by heat after patterning. Incidentally, after the laminate structure of the organic EL device up to the cathode CD is formed, this ITO is connected with a wiring connected to a plus voltage source and is made to function as the anode AD.

After the crystallizing process of the ITO, CuPc of a thickness of 6 nm as the hole transport layer, αNPD of a thickness of 50 nm as the light emitting layer, Alq3 of a thickness of 50 nm as the electron transport layer, LiF of a thickness of 0.5 nm as the electron injection layer, and aluminum (Al) of a thickness of 200 nm as the cathode are respectively formed by vacuum heat evaporation. The degree of vacuum in the vacuum heat evaporation is 10⁴ Pa or less. A wiring connected to a minus voltage source is connected to the cathode of aluminum. Next, the laminate structure is covered with sealing glass having drying agent and is sealed. Incidentally, the evaporation speed (Å/s) of Alq3 is made 1.0, the evaporation speed (Å/s) of αNPD is made 0.7, and the vacuum evaporation is performed.

FIG. 2 is a view for explaining the presence or absence of immediately preceding chamber cleaning (A), ozone cleaning (presence or absence, the number of times) (B) and the number of times of immediately preceding trial manufacture (C) in examples 1 to 4 (ex. 1 to ex. 4) and comparative examples 1 and 2 (cp. 1 and cp. 2). Further, chamber cleaning method and ozone cleaning method are as follows.

<Chamber Cleaning Method>

Detachable components such as an adhesion-preventing plate and a crucible are detached, and the accretions of organic EL material and the like are completely removed by a solvent. It is confirmed by visual examination and a UV lamp that no material adheres. Besides, cleaning under the same condition is performed and it is confirmed also by HPLC or GC-MS that no material adhere. The components after the cleaning are attached to the apparatus.

<Ozone Cleaning Method>

Ozone is introduced into the apparatus until the ozone pressure becomes 50 kPa in a state where the degree of vacuum of the evaporation apparatus is 1.0×10⁻³ pa or less. This state is held for 10 minutes, and finally, exhaustion is performed, and nitrogen replacement is performed. The number of times of the ozone cleaning is changed according to the degree of contamination of the apparatus and the cleaning is performed.

FIG. 3 is an explanatory view of fabrication conditions of light emitting devices corresponding to the examples and the comparative examples of FIG. 2. For example, the half luminance lifetime (hr) (g) of the organic EL element of example 1 is 760. The purity (%) (c) of the formed αNPD and the number of impurities (d) of the αNPD are analyzed by the HPLC, and the impurity amount (ng/cm²) (e) of the whole organic layer and the number of impurities (f) of the whole organic layer are analyzed by the GC-MS having a generated gas introduction mechanism. An analyzing method is as follows.

### [Analyzing Method: No. 1 • • Case of HPLC]

1. Sealing glass is peeled, and the sealing glass and the light emitting device are separated.
2. The organic layer of the light emitting device is dissolved in an organic solvent (methylene chloride, THF, etc.).
3. The dissolved solution is analyzed by HPLC-MS.

### <Analytical Condition (Case of Dissolution by THF)>

Analysis is performed at a gradient of H2O/CH3CN/THF=10/60/30.
4. The quantities of main component and decomposition product are measured in terms of peak area per unit area.

### [Analysis Method: No. 2 • • Case of GC-MS]

1. Sealing glass is peeled, and the sealing glass and the light emitting device are separated.
2. The separated light emitting device is analyzed by GC/MS (QP-2010) having a generated gas introduction mechanism.
3. Heating is performed to such a degree that the organic material is not decomposed, and generated gas components are analyzed.

### <Analytical Condition>

Absorbent: Tenax, adsorption tube heating temperature: 270° C., GC/MS condition: 40° C. (held for 5 minutes), thereafter 10° C./min, and then, 280° C. (held for 21 minutes).
4. The quantity of a generated gas component is determined in terms of peak area per unit area (the value is expressed in terms of hexadecane).

### EXAMPLE 2

Example 2 is different from example 1 in that the evaporation speed (Å/s) (a) of Alq3 is made 0.9, the evaporation speed (Å/s) (b) of αNPD is made 1.0, and vacuum evaporation is performed. The presence or absence of immediately preceding chamber cleaning, ozone cleaning (presence or absence, the number of times), and the number of times of immediately preceding trial manufacture are as shown in FIG. 2.

The half luminance lifetime (hr) of the light emitting device formed in this way, the purity (%) of αNPD, the number of impurities in αNPD, the impurity amount (ng/cm²) of the whole organic layer, and the number of impurities in the whole organic layer are analyzed similarly to example 1. The analysis results and the half luminance lifetime (hr) are as shown in FIG. 3.

### EXAMPLE 3

Example 3 is different from example 1 in that the evaporation speed (Å/s) of Alq3 is made 1.0, the evaporation speed (Å/s) of αNPD is made 2.0, and vacuum evaporation is performed. The presence or absence of immediately preceding chamber cleaning, ozone cleaning (presence or absence, the number of times), and the number of times of immediately preceding trial manufacture are as shown in FIG. 2.

The half luminance lifetime (hr) of the light emitting device formed in this way, the purity (%) of αNPD, the number of impurities in αNPD, the impurity amount (ng/cm²) of the whole organic layer, and the number of impurities in the whole organic layer are analyzed similarly to example 1. The analysis results and the half luminance lifetime (hr) are as shown in FIG. 3.

### EXAMPLE 4

Example 4 is different from example 1 in that the evaporation speed (Å/s) of Alq3 is made 1.0, the evaporation speed (Å/s) of αNPD is made 5.0, and vacuum evaporation is performed. The presence or absence of immediately preceding chamber cleaning, ozone cleaning (presence or absence, the number of times), and the number of times of immediately preceding trial manufacture are as shown in FIG. 2.

The half luminance lifetime (hr) of the light emitting device formed in this way, the purity (%) of αNPD, the number of impurities in αNPD, the impurity amount (ng/cm²) of the whole organic layer, and the number of impurities in the whole organic layer are analyzed similarly to example 1. The analysis results and the half luminance lifetime (hr) are as shown in FIG. 3.

### COMPARATIVE EXAMPLE 1

Comparative example 1 is different from example 1 in that the evaporation speed (Å/s) of Alq3 is made 1.0, the evaporation speed (Å/s) of αNPD is made 1.1, and vacuum evaporation is performed. The presence or absence of immediately preceding chamber cleaning, ozone cleaning (presence or absence, the number of times), and the number of times of immediately preceding trial manufacture are as shown in FIG. 2.

The half luminance lifetime (hr) of the light emitting device formed in this way, the purity (%) of αNPD, the number of impurities in αNPD, the impurity amount (ng/cm²) of the whole organic layer, and the number of impurities in the whole organic layer are analyzed similarly to example 1. The analysis results and the half luminance lifetime (hr) are as shown in FIG. 3.

### COMPARATIVE EXAMPLE 2

Comparative example 2 is different from example 1 in that the evaporation speed (Å/s) of Alq3 is made 1.0, the evaporation speed (Å/s) of αNPD is made 0.9, and vacuum evaporation is performed. The presence or absence of immediately preceding chamber cleaning, ozone cleaning (presence or absence, the number of times), and the number of times of immediately preceding trial manufacture are as shown in FIG. 2.

The half luminance lifetime (hr) of the light emitting device formed in this way, the purity (%) of αNPD, the number of impurities in αNPD, the impurity amount (ng/cm²) of the whole organic layer, and the number of impurities in the whole organic layer are analyzed similarly to example 1.

The analysis results and the half luminance lifetime (hr) are as shown in FIG. 3.

### (Analysis of Raw Material)

The purity (%) of αNPD, the number of impurities in αNPD by HPLC, the impurity amount (ng/cm²) of αNPD by HPLC, and the number of impurities in αNPD by GC-MS are analyzed similarly to example 1. The analysis results are as shown in FIG. 3.

### (Consideration)

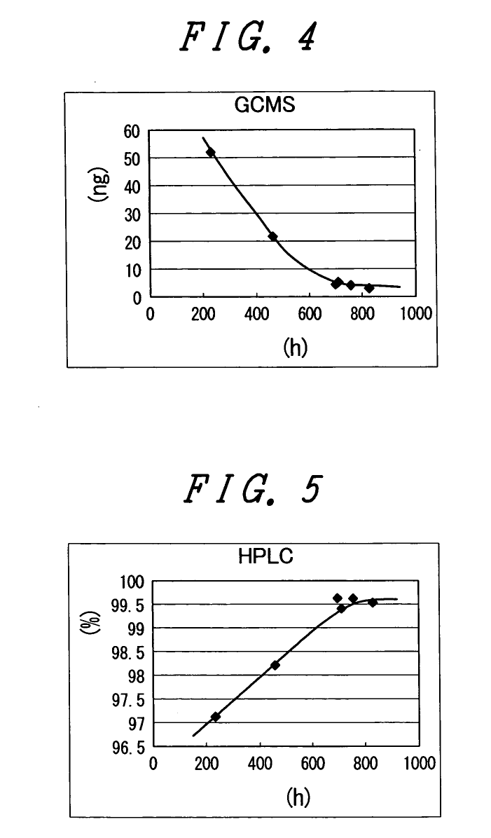

FIG. 4 is a view showing a relation between the impurity amount and the half luminance lifetime. FIG. 5 is a view showing a relation between the purity and the half luminance lifetime. From the analysis results of the HPLC in FIG. 5, it is understood that when the purity is 99.5% or more, the light emitting device having long lifetime cannot be always stably obtained. Besides, from the analysis results of the GC-MS in FIG. 4, it is understood that the light emitting device superior in lifetime characteristic has few generated gas components, and the light emitting device inferior in lifetime characteristic has many generated gas components, and the amount of generation is large. It is understood that when the impurity amount is 10 ng/cm² or less in terms of hexadecane, and the number of impurities is 10 or less, the light emitting device having long lifetime can be stably obtained.

### EXAMPLE 5

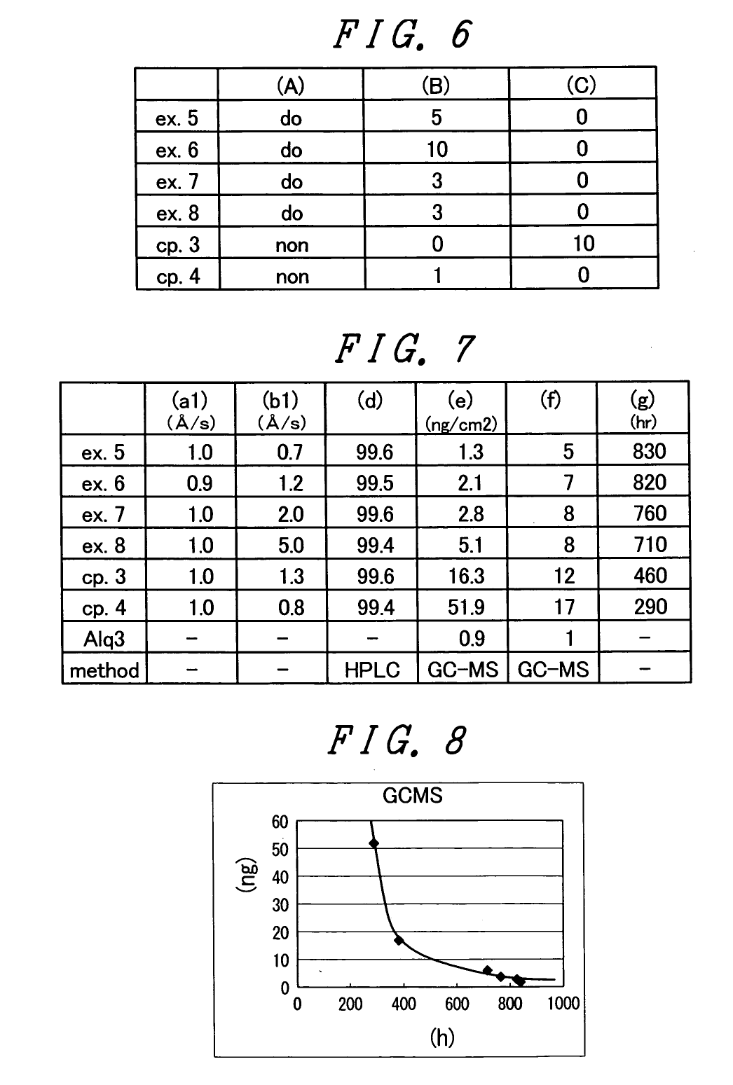

Example 5 is different from example 1 in that the evaporation speed (Å/s) of Alq3 is made 0.7, the evaporation speed (Å/s) (a1) of αNPD is made 1.0, and vacuum evaporation is performed. FIG. 6 is a view for explaining the presence or absence of immediately preceding chamber cleaning, ozone cleaning (presence or absence, the number of times), and the number of times of immediately preceding trial manufacture in examples 5 to 8 (ex. 5 to ex. 8) and comparative examples 3 and 4 (cp. 3 and cp. 4). FIG. 7 is an explanatory view of analysis results and half luminance lifetime (hr).

The half luminance lifetime (hr) (g) of the light emitting device formed in this way, the purity (%) (d) of αNPD, the impurity amount (ng/cm²) (e) of the whole organic layer, and the number of impurities (f) in the whole organic layer are analyzed similarly to example 1. The analysis results and the half luminance lifetime (hr) are as shown in FIG. 7.

### EXAMPLE 6

Example 6 is different from example 1 in that the evaporation speed (Å/s) (b1) of Alq3 is made 1.2, the evaporation speed (Å/s) of αNPD is made 0.9, and vacuum evaporation is performed. The presence or absence of immediately preceding chamber cleaning, ozone cleaning (presence or absence, the number of times), and the number of times of immediately preceding trial manufacture are as shown in FIG. 6.

The half luminance lifetime (hr) of the light emitting device formed in this way, the purity (%) of αNPD, the impurity amount (ng/cm²) of the whole organic layer, and the number of impurities in the whole organic layer are analyzed similarly to example 1. The analysis results and the half luminance lifetime (hr) are as shown in FIG. 7.

### EXAMPLE 7

Example 7 is different from example 1 in that the evaporation speed (Å/s) of Alq3 is made 2.0, the evaporation speed (Å/s) of αNPD is made 1.0, and vacuum evaporation is performed. The presence or absence of immediately preceding chamber cleaning, ozone cleaning (presence or absence, the number of times), and the number of times of immediately preceding trial manufacture are as shown in the drawing.

The half luminance lifetime (hr) of the light emitting device formed in this way, the purity (%) of αNPD, the impurity amount (ng/cm²) of the whole organic layer, and the number of impurities in the whole organic layer are analyzed similarly to example 1.

The analysis results and the half luminance lifetime (hr) are as shown in FIG. 7.

### EXAMPLE 8

Example 8 is different from example 1 in that the evaporation speed (Å/s) of Alq3 is made 5.0, the evaporation speed (Å/s) of αNPD is made 1.0, and vacuum evaporation is performed. The presence or absence of immediately preceding chamber cleaning, ozone cleaning (presence or absence, the number of times), and the number of times of immediately preceding trial manufacture are as shown in FIG. 6.

The half luminance lifetime (hr) of the light emitting device formed in this way, the purity (%) of αNPD, the impurity amount (ng/cm²) of the whole organic layer, and the number of impurities in the whole organic layer are analyzed similarly to example 1. The analysis results and the half luminance lifetime (hr) are as shown in FIG. 7.

### COMPARATIVE EXAMPLE 3

Comparative example 3 is different from example 1 in that the evaporation speed (Å/s) of Alq3 is made 5.0, the evaporation speed (Å/s) of αNPD is made 1.0, and vacuum evaporation is performed. The presence or absence of immediately preceding chamber cleaning, ozone cleaning (presence or absence, the number of times), and the number of times of immediately preceding trial manufacture are as shown in FIG. 6.

The half luminance lifetime (hr) of the light emitting device formed in this way, the purity (%) of αNPD, the impurity amount (ng/cm²) of the whole organic layer, and the number of impurities in the whole organic layer are analyzed similarly to example 1. The analysis results and the half luminance lifetime (hr) are as shown in FIG. 7.

### COMPARATIVE EXAMPLE 4

Comparative example 4 is different from example 1 in that the evaporation speed (Å/s) of Alq3 is made 5.0, the evaporation speed (Å/s) of αNPD is made 1.0, and vacuum evaporation is performed. The presence or absence of immediately preceding chamber cleaning, ozone cleaning (presence or absence, the number of times), and the number of times of immediately preceding trial manufacture are as shown in FIG. 6.

The half luminance lifetime (hr) of the light emitting device formed in this way, the purity (%) of αNPD, the impurity amount (ng/cm²) of the whole organic layer, and the number of impurities in the whole organic layer are analyzed similarly to example 1. The analysis results and the half luminance lifetime (hr) are as shown in FIG. 7.

### (Consideration)

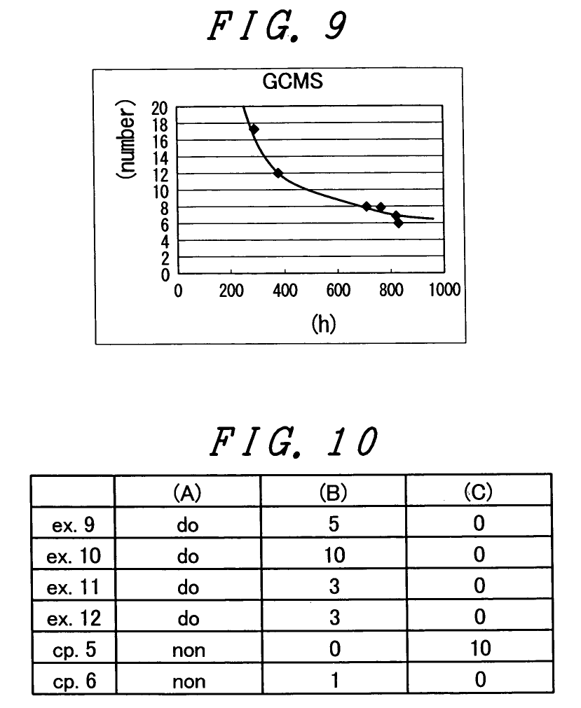

FIG. 8 is a view for explaining a relation between the impurity amount of the whole organic layer and the half luminance lifetime. FIG. 9 is a view for explaining a relation between the number of impurities and the half luminance lifetime. From the analysis results of GC-MS in FIG. 8 and FIG. 9, it is understood that the light emitting device excellent in lifetime characteristic has few generated gas components, and the light emitting device inferior in lifetime has many generated gas components, and the amount of generation is large. It is understood that when the impurity amount is 10 ng/cm² or less in terms of hexadecane as shown in FIG. 8, and when the number of impurities is 10 or less as shown in FIG. 9, the light emitting device having long lifetime can be stably obtained.

### EXAMPLE 9

Example 9 is different from example 2 in that instead of CuPc, TNATA of 20 nm is used for the hole transport layer HTL, and the thickness of αNPD is made as thin as 40 nm. Incidentally, the evaporation speed (Å/s) (b1) of Alq3 is made 1.0, the evaporation speed (Å/s) (a1) of αNPD is made 1.0, the evaporation speed (Å/s) (c1) of TNATA is made 0.7, and vacuum evaporation is performed. The presence or absence of immediately preceding chamber cleaning, ozone cleaning (presence or absence, number of times), and the number of times of immediately preceding trial manufacture are shown in FIG. 10.

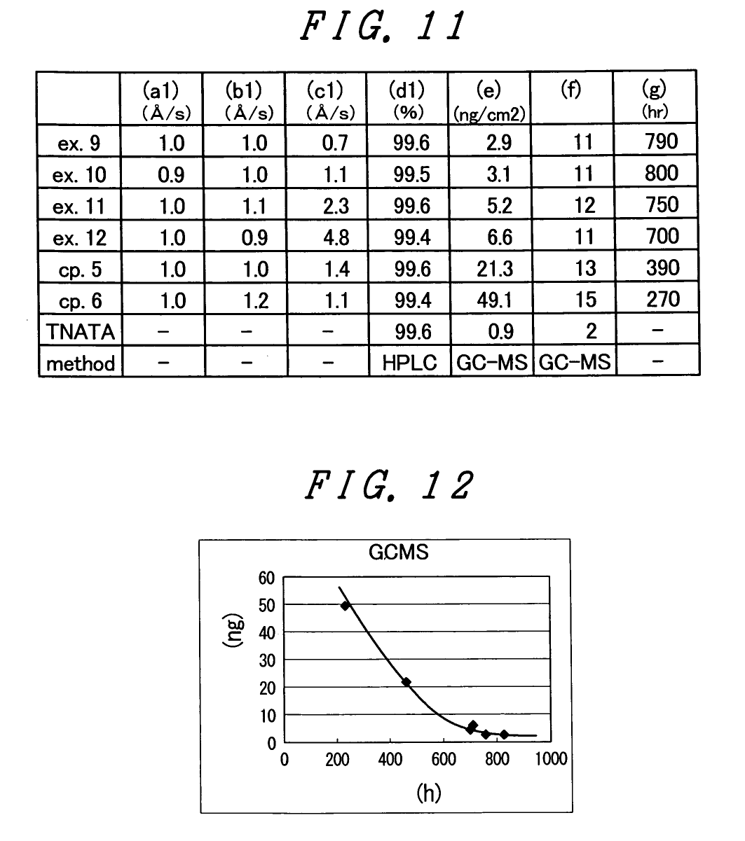

The half luminance lifetime (hr) (g) of the light emitting device formed in this way, the purity (%) (d1) of TNATA, the impurity amount (ng/cm²) (e) of the whole organic layer, and the number of impurities (f) in the whole organic layer are analyzed similarly to example 1. The analysis results and the half luminance lifetime (hr) are shown in FIG. 11.

### EXAMPLE 10

Example 10 is different from example 1 in that the evaporation speed (Å/s) of Alq3 is made 1.0, the evaporation speed (Å/s) of αNPD is made 0.9, the evaporation speed (Å/s) of TNATA is made 1.1, and vacuum evaporation is performed. The presence or absence of immediately preceding chamber cleaning, ozone cleaning (presence or absence, the number of times), and the number of times of immediately preceding trial manufacture are as shown in FIG. 11.

The half luminance lifetime (hr) of the light emitting device formed in this way, the purity (%) of TNATA, the impurity amount (ng/cm²) of the whole organic layer, and the number of impurities in the whole organic layer are analyzed similarly to example 1. The analysis results and the half luminance lifetime (hr) are shown in FIG. 11.

### EXAMPLE 11

Example 11 is different from example 1 in that the evaporation speed (Å/s) of Alq3 is made 1.1, the evaporation speed (Å/s) of αNPD is made 1.0, the evaporation speed (Å/s) of TNATA is made 2.3, and vacuum evaporation is performed. The presence or absence of immediately preceding chamber cleaning, ozone cleaning (presence or absence, the number of times), and the number of times of immediately preceding trial manufacture are as shown in FIG. 10.

The half luminance lifetime (hr) of the light emitting device formed in this way, the purity (%) of TNATA, the impurity amount (ng/cm²) of the whole organic layer, and the number of impurities in the whole organic layer are analyzed similarly to example 1. The analysis results and the half luminance lifetime (hr) are shown in FIG. 11.

### EXAMPLE 12

Example 12 is different from example 1 in that the evaporation speed (Å/s) of Alq3 is made 0.9, the evaporation speed (Å/s) of αNPD is made 1.0, the evaporation speed (Å/s) of αTNATA is made 4.8, and vacuum evaporation is performed. The presence or absence of immediately preceding chamber cleaning, ozone cleaning (presence or absence, the number of times), and the number of times of immediately preceding trial manufacture are as shown in FIG. 10.

The half luminance lifetime (hr) of the light emitting device formed in this way, the purity (%) of TNATA, the impurity amount (ng/cm²) of the whole organic layer, and the number of impurities in the whole organic layer are analyzed similarly to example 1. The analysis results and the half luminance lifetime (hr) are shown in FIG. 11.

### COMPARATIVE EXAMPLE 5

Comparative example 5 is different from example 1 in that the evaporation speed (Å/s) of Alq3 is made 1.0, the evaporation speed (Å/s) of αNPD is made 1.0, the evaporation speed (Å/s) of TNATA is made 1.4, and vacuum evaporation is performed. The presence or absence of immediately preceding chamber cleaning, ozone cleaning (presence or absence, the number of times), and the number of times of immediately preceding trial manufacture are as shown in FIG. 10.

The half luminance lifetime (hr) of the light emitting device formed in this way, the purity (%) of TNATA, the impurity amount (ng/cm²) of the whole organic layer, and the number of impurities in the whole organic layer are analyzed similarly to example 1. The analysis results and the half luminance lifetime (hr) are shown in FIG. 11.

### COMPARATIVE EXAMPLE 6

Comparative example 6 is different from example 1 in that the evaporation speed (Å/s) of Alq3 is made 1.2, the evaporation speed (Å/s) of αNPD is made 1.0, the evaporation speed (Å/s) of TNATA is made 1.1, and vacuum evaporation is performed. The presence or absence of immediately preceding chamber cleaning, ozone cleaning (presence or absence, the number of times), and the number of times of immediately preceding trial manufacture are as shown in FIG. 10.

The half luminance lifetime (hr) of the light emitting device formed in this way, the purity (%) of TNATA, the impurity amount (ng/cm²) of the whole organic layer, and the number of impurities in the whole organic layer are analyzed similarly to example 1. The analysis results and the half luminance lifetime (hr) are shown in FIG. 11.

### (Consideration)

FIG. 12 is a view for explaining a relation between the impurity amount and the half luminance lifetime. From FIG. 12, it is understood that when the impurity amount is 10 or less, the light emitting device having long lifetime can be stably obtained.

1. A light emitting device comprising at least one organic compound layer between a pair of electrodes, wherein
a content of an impurity generated from an organic compound in the at least one organic compound layer is 10 ng/cm² or less in terms of hexadecane.

2. The light emitting device according to claim 1, wherein the layer including the impurity is a hole injection layer or a hole transport layer.

3. The light emitting device according to claim 1, wherein the impurity is one selected from the group consisting of a decomposition product of the organic compound constituting the hole injection layer or the hole transport layer, a decomposition polymerization product thereof, and a polymerization product thereof.

4. The light emitting device according to claim 1, wherein the impurity is an aromatic amine compound.

5. The light emitting device according to claim 1, wherein the aromatic amine compound includes at least one kind of compound selected from the group consisting of diphenylamine or its derivative, triphenyl amine or its derivative, naphthylamine or its derivative, and biphenyldiamine or its derivative.

6. The light emitting device according to claim 1, wherein the impurity is an aromatic compound.

7. The light emitting device according to claim 6, wherein the impurity includes at least one kind of compound selected from the group consisting of a benzene derivative, a naphthalene derivate, and a biphenyl derivative.

8. The light emitting device according to claim 1, wherein the layer including the impurity is a light emitting layer.

9. The light emitting device according to claim 1, wherein the impurity is a decomposition product of the organic compound constituting the light emitting layer.

10. The light emitting device according to claim 1, wherein the impurity is a decomposition product of the organic compound forming a host of the light emitting layer.

11. The light emitting device according to claim 1, wherein the impurity is a decomposition product of the organic compound forming a guest of the light emitting layer.

12. The light emitting device according to claim 1, wherein the layer including the impurity is an electron transport layer.

13. The light emitting device according to claim 1, wherein the impurity is one selected from the group consisting of a decomposition product of the organic compound constituting the electron transport layer, a decomposition polymerization product thereof, and a polymerization product thereof.

14. The light emitting device according to claim 1, wherein the impurity is a decomposition product of quinolinol aluminum complex.

15. The light emitting device according to claim 1, wherein the impurity is quinolinol.
